(19) United States
(12) Patent Application Publication
(10) Pub. No.: US 2021/0182453 A1
(43) Pub. Date: Jun. 17, 2021

(54) APPLICATION BEHAVIOR IDENTIFICATION

(71) Applicant: Hewlett-Packard Development Company, L.P., Spring, TX (US)

(72) Inventors: Mauricio Coutinho Moraes, Porto Alegre (BR); Daniele Antunes Pinheiro, Porto Alegre (BR); Cristiane Machado, Porto Alegre (BR); Joan Alminhana Bernardes, Porto Alegre (BR)

(73) Assignee: Hewlett-Packard Development Company, L.P., Spring, TX (US)

(21) Appl. No.: 16/761,942

(22) PCT Filed: Dec. 22, 2017
(86) PCT No.: PCT/US2017/068265

§ 371 Date: May 6, 2020

(51) Int. Cl. G06F 30/20; G06F 16/36; G06F 16/338; G06F 11/36

(52) U.S. Cl. CPC G06F 30/20; G06F 16/36; G06F 11/3692; G06F 11/3684; G06F 16/338

(57) ABSTRACT

A method of identifying behaviors of an application is disclosed. A dictionary of key-value pairs is generated from a plurality of simulated requests to an application is provided. Each simulated request generates a log message having a key and a corresponding value. Log entries from actual request to the application are matched with the dictionary to discover expected behaviors.

### BACKGROUND

Many computing systems, such as applications running on a computing device, employ a log file, or log, to record events as messages that occur in an operating system and the application. The act of keeping a log or recording events as messages, or log entries, is referred to as logging. In one example, log messages can be written to a single log file. Log entries can include a record of events that have occurred in the execution of the system or application that can be used to understand the activities for system management, security auditing, general information, analysis, and debugging and maintenance. Many operating systems, frameworks, and programming include a logging system. In some examples, a dedicated, standardized logging system generates filters, records, and presents log entries recorded in the log.

### BRIEF DESCRIPTION OF THE DRAWINGS

FIG. 1 is a block diagram illustrating an example method.

FIG. 2 is a block diagram illustrating an example method of the example method of FIG. 1.

FIG. 3 is a schematic diagram illustrating an example system to implement at least a feature of the example method of FIG. 1.

FIG. 4 is a schematic diagram illustrating an example system to implement at least another feature of the example method of FIG. 1.

### DETAILED DESCRIPTION

Developers may employ solutions for identifying behaviors in computer applications, such as browser-based web applications, used in production environments, which can include post-release of the application or what many developers often colloquially refer to as “the wild.” Many applications generate extensive log files that record details of operations such as what resources where accessed and by whom, activities performed, errors or exception encountered. The volume of log entries for an application or infrastructure can become unwieldy. Log management and analysis solutions enable organizations to determine collective, actionable intelligence from the sea of data.

Log management and analysis solutions can include proprietary and open source offerings that provide log management and analysis platforms or consolidated data analytics platforms. For example, solutions can employ a toolset having a distributed RESTful search and analytics engine, a distributed pipeline, a data visualization, and agent-based purposed data shipping, or can employ discreet tools of the toolset. Such solutions can be employed for processing, indexing, and querying log files, plus a visualization that allows users to detect high-level overviews of application behavior and low-level keyword occurrences. Generally, though, users of such solutions manually define application-specific queries.

The application can present many behaviors that can depend on many factors or different combinations of factors present in the production environment. The solutions of the disclosure can automatically identify from application log files what expected behaviors and unexpected behaviors have been performed in greater detail than by analyzing inputs and outputs of the application or using textual abstraction inherent in log files via other log management and analysis solutions. The solution can provide troubleshooting of applications at a relatively low cost in which issues can be detected at the behavior level rather than the textual level inherent in log files. The level abstraction for troubleshooting is increased, which can potentially lower costs of troubleshooting, such as on-call operations. The solution can provide improved communication through the automatic generation of summaries of aggregated data and security through identification of anomalous application usage patterns.

In one example, the solution includes a training phase performed in a controlled environment and a matching phase performed in the production environment. The training phase subjects the application to requests to produce various behaviors the application may be expected to provide in a production environment. The matching phase identifies what of the expected behaviors, and can identify what unexpected behaviors, actually occurred in the production environment.

During the training phase, the application is subjected to a set of behaviors in the form of requests. These requests can include requests that the application can be the same or similar to requests the application may be expected to encounter in the production environment, but in the training phase, the requests can be termed “test requests” or “simulated requests.” The simulated requests include labels, or descriptions of the behaviors, however, which may be missing from requests in the production environment.

In general, logging includes generating log entries or log messages, and such terms are often used interchangeably. In this disclosure, an application generates a “log message” or “log messages” from simulated requests such as during the training phase. An application otherwise generates a “log entry” or “log entries,” such as in production environments, the matching phase, or in periods of development prior to or subsequent to the training phase.

For each simulated request, the application generates a log message that includes the label associated with the request and a corresponding location of the application that generated the log message. The label can include a description of the behavior or the request, and the location can include the location of the application, such as the source code location, that generated the log message. In one example, the log messages can be stored in a log file. After a set including different simulated requests is presented to the application, the log messages in the log file are extracted to generate a dictionary of key-value pairs in which the location of the application that generated the log entry is the key and the label is the corresponding value. The value can be written in the log message in a way to possibly infer them during the matching phase in which log entries are written to the log file without the value.

During the matching phase, the application is permitted to field actual requests intended for the application in the production environment and generate corresponding log entries in the log file. Typically, the actual requests do not include a label as included in the simulated requests, but the log entries include a location of the application that generated the log entry. The log entries can be selectively extracted from the log file. The log entries are received and applied against the dictionary. Log entries with locations of the application for which there is a direct match to the dictionary are expected behaviors and log entries for which there is no match to the dictionary are unexpected behaviors.

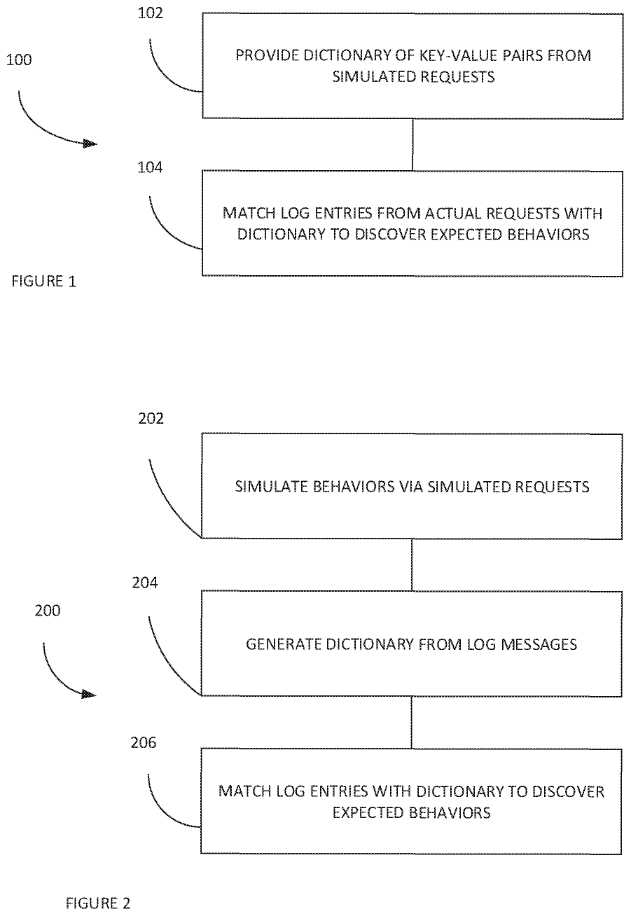

FIG. 1 illustrates an example method 100 of identifying behaviors of an application. A dictionary of key-value pairs is generated from a plurality of simulated requests to an application is provided at 102. Each simulated request generates a log message having a key and a corresponding value. Log entries from actual request to the application are matched with the dictionary to discover expected behaviors at 104.

The dictionary and associated key-value pairs can be agnostic to particular formats, such as log formats or computer languages. For example, the dictionary and key-value pairs can be constructed from free-text based logs, logs in the JSON format, or logs in any format. The JSON format and associated terms are used as illustration.

In one example, the dictionary of key-value pairs at 102 can be generated from a set of simulated requests that include expected behaviors of the application in the production environment. For instance, in the case of the application as a multi-tiered, web application, expected behaviors can include a response to an unauthorized attempt to access the application, a response to an invalid input to the application, a response a successful access and valid input, and other responses in general or specific to the application. Each of these responses can be generated via requests to the application, and the application can generate a log message or log entry to a log file for each request.

To generate the dictionary at 102, simulated requests are provided to the application to generate log messages in which each simulated request generates a corresponding log message. The log messages may be stored in and subsequently extracted from a log file. Each log message includes a key and corresponding value. For example, a key can include a location in the application that generated the behavior of the simulated request and the corresponding value can include a label, such as description of the behavior or some non-arbitrary information or code that can correspond with the behavior. In this example, the label is added to the simulated request in such a way that the label is associated with each log message generated with the application, such as by instrumenting the source code to provide such a feature. In one example, the key can include an identification of the source code of the application that generated the behavior and the value can include a short description of the behavior. In general, the key includes a “log location,” which does not refer to the location of the log file but instead means the location in the application that generated the behavior, such as the location of the corresponding source code, execution path, or other suitable identifier. For example, the key can include a combination of more than one log locations. After a selected amount of simulated requests are provided to the application, the dictionary is generated from log messages to include the key-value pair. As the application evolves or selected features of the application become a point of emphasis, the dictionary can be amended to include or delete selected key-value pairs.

Log entries from actual request to the application are generated as part of production environment and included in a log file. In general, the actual requests do not include labels as part of values as in the simulated request. Each of the log entries from the actual requests might not include the labels or descriptions of the behaviors or requests that generated the log entry. Each of the log entries, however, includes the log location, such as the location of the source code in the application that generated the behavior. In one example, the log entries are extracted from the log file and compared with the dictionary. A log entry is compared with the dictionary to determine whether the log location of the log entry is found as a key in the dictionary at 104. If there is a match between the log location of the log entry and a key in the dictionary, the behavior corresponding with the log entry is expected of the application in the production environment. If there is no match between the log location of the log entry and a key in the dictionary, the behavior corresponding with the log entry is unexpected in the production environment.

Method 100 can be included as part of a tool to provide processing, indexing, and querying the log entries as well as to provide a detailed analysis and visualization of expected behaviors and unexpected behaviors at 104. Method 100 provides a relatively simple or straightforward approach to identifying behaviors of the application from log entries including expected behaviors and unexpected behaviors. In the illustrated example, method 100 does not employ probabilistic models—such as Naïve Bayes, Support Vector Machine (SVM), or Decision Trees—to perform the matching as is typically included in solutions that include machine-learning features. A practical consequence is that method 100 can operate to discover behaviors without relatively large amounts of data applied during a training phase. Analysis developed from the use of method 100 can provide low-cost troubleshooting and improved software quality. Method 100 also provides a solution to also analyze free-format log files, in which free-format log files are contrasted to standard log formats that present a specific set of predefined columns.

The example method 100 can be implemented to include a combination of one or more hardware devices and computer programs for controlling a system, such as a computing system having a processor and memory, to perform method 100 to identify behaviors of an application. Examples of computing system can include a server or workstation, a mobile device such as a tablet or smartphone, a personal computer such as a laptop, and a consumer electronic device, or other device. Method 100 can be implemented as a computer readable medium or computer readable device having set of executable instructions for controlling the processor to perform the method 100. In one example, computer storage medium, or non-transitory computer readable medium, includes RAM, ROM, EEPROM, flash memory or other memory technology, that can be used to store the desired information and that can be accessed by the computing system. Accordingly, a propagating signal by itself does not qualify as storage media. Computer readable medium may be located with the computing system or on a network communicatively connected to the application of interest, such as a multi-tiered, web-based application, or to the log file of the application of interest. Method 100 can be applied as computer program, or computer application implemented as a set of instructions stored in the memory, and the processor can be configured to execute the instructions to perform a specified task or series of tasks. In one example, the computer program can make use of functions either coded into the program itself or as part of library also stored in the memory.

FIG. 2 illustrates an example method 200 implementing method 100. Behaviors of the application are simulated via simulated requests at 202. Each simulated request at 202 generates a log message having a key and corresponding value. A dictionary is generated with key-value pairs extracted from the log messages at 204. Log entries resulting from actual requests are matched with the key-value pairs in the dictionary to discover expected behaviors at 206, and also unexpected behaviors. The discovery and analysis of the expected behaviors and unexpected behaviors provides for user to search for problems at the behavior level, which is higher than the typical textual level inherent to log files, and can deliver a relatively lower cost diagnosis.

The method 200 can be extended to provide additional features or functionality. Additionally, behaviors can be provided via a generation of summaries of aggregated data, which can include graphs or charts in a visualization. The method 200 can also provide for event monitoring and alerting for cases of unexpected behaviors or selected expected behaviors as well as additional features.

Behaviors of the application are simulated via simulated requests at 202 during a training phase. Functional tests of the application can simulate a host of expected behaviors of the application. The expected behaviors can include a far reaching range of different expected behaviors or a selected set of expected behaviors. The application can include features, such as code, for logging such as to generate log messages or log entries into a log file. For example, an application written in the Java computer language can make use of java.util.logging package, and many logging frameworks are available for a variety of computer languages. Each simulated request at 202 generates a log message having a key and corresponding value. In one example, each simulated request at 202 generates a log message having a log location as a key and a corresponding label at the value.

Labels are included with the simulated requests in such a way that the labels are associated with each log message generated from the simulated request. In one example, the code can be instrumented to add the value of the label to the log message as a string. Label values can include a description that generated the behavior, such as MISSING_PARAMETER or INVALID_PARAMETER, which may return an HTTP status 400, or such as VALID_PARAMETER or VALID_INPUT, which may return an HTTP status 200. In one example, the label values can include self-explanatory descriptions of the behavior or otherwise have meaning to the developer.

The application can be instrumented to include a log location to the log message. In one example, the log location can include a class name appended to a line number of a method call that generated the log message. Other suitable log locations are possible and can be selected based on a consideration that includes the type of application, programming paradigm, the computer language, or developer preference. In one example, the code or execution path that generated the log message can be included in the log message as a string. Some log libraries or frameworks can provide ready-to-use log location support that can be added to an application, and one such framework or Java-based logging utility is available under the trade designation Log 4j from The Apache Software Foundation of Forest Hill, Maryland, U.S.A.

The following examples including an application of interest having routines and logs are provided to illustrate particular implementations of method 200. Other implementations are contemplated. For example, method 200 can be implemented with other applications than those written in the Java computer language and with log messages or entries in format other than Java Script Object Notation (JSON) format as illustrated.

As an example, an application of interest can receive a numeric parameter. In this example, the application can include a class EDP having a receiveParameter( ) method. If the parameter received by this code is present and positive, the operation will execute successfully and return an HTTP status code 200. Otherwise, the operation will fail and return an HTTP status code 400. Three different behaviors, or execution paths, are possible for the application of interest, which can lead to three different log messages or log entries, or three different sets of log messages or log entries. For example, no parameter may be present, resulting in a “missing parameter” log entry. Also, the parameter may be negative, resulting in an “invalid parameter” log entry. Further, the parameter may be positive, resulting in a “valid parameter” log entry. Additionally, the application of interest can print the received parameter as a log entry. As an example the log entries of application not yet prepared for the simulated requests at 202 can appear as:

For a null or missing parameter, the generated log entries are:
{“message”: “received a null parameter”}
{“message”: “missing parameter”}

For a negative parameter, such as −1, the generated log entries are:
{“message”: “received a −1”}
{“message”: “invalid parameter”}

For a positive parameter, such as 1, the generated log entries are:
{“message”: “received a 1”}
{“message”: “valid parameter”}

The application include the class EDP having the receiveParameter( ) method can be instrumented to add a log location to the log messages and log entries, and at least during the training phase, the application can include instrumentation to provide labels in the log messages. For example, requests that send a null parameter to the application can include a label of “MISSING_PARAM”, requests that send a negative parameter such as −1 to the application can include a label of “INVALID_PARAM”, and requests that send a positive parameter such as 1 to the application can include a label of “VALID_PARAM.” Also in this example, the application is instrumented via a logging utility to generate the class name and line number of the method call as the log location in the log messages and log entries. The example log messages of an application prepared, or instrumented, for simulated requests would also include labels and log locations, and can appear as:

For a null or missing parameter, the generated log messages are:
{“message”: “received a null parameter”, “location”: “EDP.3”, “label”: “MISSING_PARAM”}
{“message”: “missing parameter”, “location”: “EDP.5”, “label”: “MISSING_PARAM”}

For a negative parameter, such as −1, the generated log messages are:
{“message”: “received a −1”, “location”: “EDP.3”, “label”: “INVALID_PARAM”}
{“message”: “invalid parameter”, “location”: “EDP.8”, “label”: “INVALID_PARAM”}

For a positive parameter, such as 1, the generated log messages are:
{“message”: “received a 1”, “location”: “EDP.3”, “label”: “VALID_PARAM”}
{“message”: “valid parameter”, “location”: “EDP.11”, “label”: “VALID_PARAM” }

A dictionary is generated with key-value pairs extracted from the log messages at 204. For example, the dictionary can be generated from the log files after the expected behaviors are simulated from the simulated requests. The dictionary includes a set of key-value pairs associated with the expected behaviors. For example, the keys can include an ordered sequence of the log locations and the values are labels extracted from the log messages. A dictionary that maps the log locations to the labels from the example expected behaviors of the application that includes the class EDP having the receiveParameter( ) method described above can include:
[“EDP.3”, “EDP.5”] “MISSING_PARAM”
[“EDP.3”, “EDP.8”] “INVALID_PARAM”
[“EDP.3”, “EDP.11”] “VALID_PARAM”

As the application processes the actual requests in a production environment, the application generates log entries into a log file. In the production environment, the actual requests to the application can be devoid of the labels. The application can be instrumented to include a log location in each log entry. During analysis of the log files, the log entries can be extracted and compared to the dictionary.

Log entries resulting from actual requests are matched with the key-value pairs in the dictionary to discover expected behaviors at 206. The log location or log location sequences generated during the training phase will match with the log location or log location sequences of the key in the dictionary for expected behaviors. The labels can be inferred from the dictionary. For example, a log entry including a particular log location sequence found in the dictionary, or key, can be inferred to include the label, or value, corresponding to the key in the dictionary. Any log location or log location sequences not found in the dictionary will result from unexpected behaviors of the application. For example, if a log entry includes a particular log location sequence not found in the dictionary, it can be inferred that the actual request that generated the log entry did not have a corresponding simulated request in the training phase.

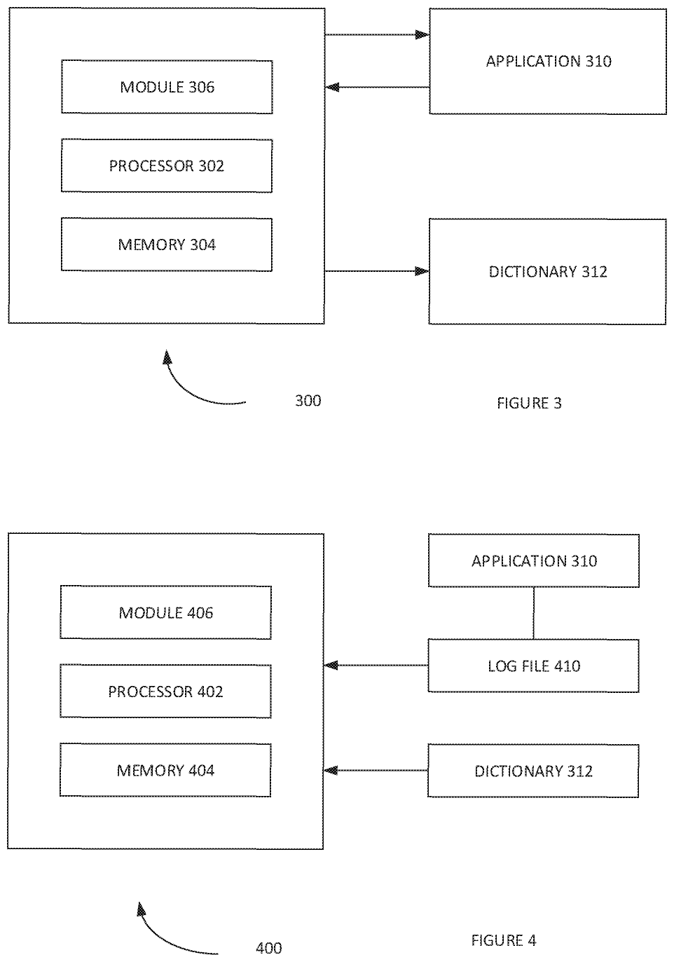

FIG. 3 illustrates an example system 300 to implement method 100 or features of method 100. The system 300 includes computing device having a processor 302 and memory 304. Depending on the configuration and type of computing device of system 300, memory 304 may be volatile (such as random access memory (RAM)), non-volatile (such as read only memory (ROM) or flash memory), or some combination of the two. The system 300 can take one or more of several forms. Such forms include a tablet, a personal computer, a workstation, a server, or a handheld device, and can be a stand-alone device or configured as part of a computer network. The memory 304 can store at least a training module 306 aspect of method 100 as set of computer executable instructions for controlling the computer system 300 to perform features of method 100.

The system 300 can include communication connections to communicate with other systems or computer applications. In the illustrated example, the system 300 is operably coupled to an application of interest 310 stored in a memory and executing in a processor. In one example, the application 310 is a web-based application, or web app, and includes features for generating log messages including a key and value such as log location and associated label included with a request. In the illustrated example, the system 300 and application 310 are in a controlled environment such as a training environment during a training phase. The system 300, such as via training module 306 and a communication connection with the application 310, can apply a simulated request including a label to the application 310 and receive a log message generated in response to the simulated request from a log file in a memory device. The system 300 can generate a dictionary 312 from keys and values extracted from log messages. The dictionary 312 can be stored in memory device 304 or in a memory device communicatively coupled to the system 300.

FIG. 4 illustrates an example system 400 to implement method 100 or features of method 100. The system 400 includes computing device having a processor 402 and memory 404. Depending on the configuration and type of computing device of system 400, memory 404 may be volatile (such as random access memory (RAM)), non-volatile (such as read only memory (ROM) or flash memory), or some combination of the two. The system 400 can take one or more of several forms. Such forms include a tablet, a personal computer, a workstation, a server, or a handheld device, and can be a stand-alone device or configured as part of a computer network. The memory 404 can store at least a matching module 406 aspect of method 100 as set of computer executable instructions for controlling the computer system 400 to perform features of method 100. System 300 can be the same or different from system 400. The system 400 can include communication connections to communicate with other system or computer application.

In the illustrated example, the system 400 is operably coupled to a log file 410 of the application of interest 310 as well as to the dictionary 312. The log file 410 may be stored on a memory device, and the system 400 may access the log file 410 via a communication connection. In the illustrated example, the application 310 can be in a production environment. For example, the application 310 may be stored and executed on a production server that is accessed by a client over a communication connection such as the internet. The client may provide actual requests to the application 310, and the application 310 generates log entries in the log file 410. The matching module 406 is able to implement features of method 100 to match log locations in the log entries to the dictionary to determine expected behaviors and unexpected behaviors. Matching module 410 can include other features to implement analysis of the behaviors.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1. A method of identifying behaviors of an application, the method comprising:
providing a dictionary of key-value pairs from a plurality of simulated requests to an application in which each simulated request generates a log message having a key and corresponding value; and
matching log entries from actual request to the application with the dictionary to discover expected behaviors.

2. The method of claim 1 wherein the key includes a location of the application generating the log message and the corresponding value includes a label.

3. The method of claim 2 where in the label includes a description of a behavior associated with the simulated request.

4. The method of claim 1 wherein the matching includes determining expected behaviors from log entries associated with a log message.

5. The method of claim 1 wherein the log entries from actual requests each include a log location of the application generating the log entries.

6. The method of claim 1 providing a set of discovered expected behaviors from matched log entries and a set of unexpected behaviors from unmatched log entries.

7. A non-transitory computer readable medium to store computer executable instructions to control a processor to:
generate a dictionary from a plurality of simulated requests to an application in which each simulated request generates a log message that includes a key and corresponding value pair, wherein log entries from actual request to the application matched with the dictionary include expected behaviors and log entries from actual request to the application not matched with the dictionary include unexpected behaviors.

8. The computer readable medium of claim 7 wherein log messages are extracted from a log file to determine the key and corresponding value pair.

9. The computer readable medium of claim 7 wherein the key includes a location of the application to generate the log message and the corresponding value includes a description of the simulated request.

10. The computer readable medium of claim 9 wherein the location of the application includes a location in source code of the application.

11. The computer readable medium of claim 7 to generate a visualization of the expected behaviors and unexpected behaviors.

12. A system, comprising:
memory to store a set of instructions; and
a processor to execute the set of instructions to:
simulate a plurality of behaviors via simulated requests to the application in which each simulated request generates a log message including a key and corresponding value pair;
generate a dictionary with the key value pairs from the log messages of the simulated requests; and
match log entries of actual requests to the dictionary to discover expected behaviors.

13. The system of claim 12 including a log analysis platform to include the dictionary and match log entries.

14. The system of claim 13 wherein the analysis provides a report of matched log entries.

15. The system of claim 12 wherein each log entry includes a location of the application to generate the log entry in response to the actual request.
